(19) United States
(12) Patent Application Publication
(10) Pub. No.: US 2016/0312380 A1
(43) Pub. Date: Oct. 27, 2016

(54) Ga2O3 BASED CRYSTAL FILM FORMING METHOD, AND CRYSTAL LAMINATED STRUCTURE

(71) Applicant: TAMURA CORPORATION, Tokyo (JP)

(72) Inventor: Kohei SASAKI, Tokyo (JP)

(73) Assignee: TAMURA CORPORATION, Tokyo (JP)

(21) Appl. No.: 15/135,667

(22) Filed: Apr. 22, 2016

(30) Foreign Application Priority Data
Apr. 23, 2015 (JP) 2015-088724

(51) Int. Cl. C30B 23/02; C30B 29/68; C30B 29/16

(52) U.S. Cl. CPC C30B 23/025; C30B 29/16; C30B 29/68

(57) ABSTRACT

A Ga₂O₃ based crystal film forming method includes epitaxially growing a Ga₂O₃ based crystal film over a Ga₂O₃ based substrate. A growth temperature for the crystal film is not lower than 560 degrees Celsius. A VI/III ratio in an atmosphere adjacent to a growing surface when the crystal film is grown is smaller than ½, or greater than 2. A crystal laminated structure includes a Ga₂O₃ based substrate including a first group IV element, and a Ga₂O₃ based crystal film including a second group IV element, the crystal film being formed over the substrate, and having a surface roughness (RMS) of smaller than 1 nm, and a thickness of not smaller than 300 nm. A coefficient of variation of a concentration distribution of the second group IV element in a depth direction in the crystal film is not more than 20 percent.

The present application is based on Japanese patent application No. 2015-088724 filed on Apr. 23, 2015, the entire contents of which are incorporated herein by reference.

### BACKGROUND OF THE INVENTION

1. Field of the Invention

This invention relates to a Ga₂O₃ (gallium oxide) based crystal film forming method, and a crystal laminated structure.

2. Description of the Related Art

A technique for epitaxially growing a Ga₂O₃ based crystal film over a Ga₂O₃ based substrate is known. See e.g., Patent Document 1 below. Patent Document 1 discloses that a plane direction of a principal plane of the Ga₂O₃ based substrate is selected so as to control the growth rate of the Ga₂O₃ based crystal film.

[Patent Document 1] WO 2013/035464

### SUMMARY OF THE INVENTION

It is one object of the present invention to provide a Ga₂O₃ based crystal film forming method that allows the forming of a Ga₂O₃ based crystal film superior in crystal quality, as well as a crystal laminated structure with the Ga₂O₃ based crystal film.

According to an embodiment of the invention, a Ga₂O₃ based crystal film forming method defined by [1] to [5] below is provided. Also, according to another embodiment of the invention, a crystal laminated structure defined by [6] below is provided.

[1] A Ga₂O₃ based crystal film forming method, comprising epitaxially growing a Ga₂O₃ based crystal film over a Ga₂O₃ based substrate,

wherein a growth temperature for the Ga₂O₃ based crystal film is not lower than 560 degrees Celsius, and

wherein a VI/III ratio in an atmosphere adjacent to a growing surface when the Ga₂O₃ based crystal film is grown is smaller than ½, or greater than 2.

[2] The Ga₂O₃ based crystal film forming method according to [1], wherein the growth temperature is lower than 750 degrees Celsius.

[3] The Ga₂O₃ based crystal film forming method according to [2], further comprising doping the Ga₂O₃ based crystal film with a group IV element while growing the crystal film,

wherein the growth temperature is not higher than 650 degrees Celsius, and

wherein the VI/III ratio is not smaller than 10.

[4] A Ga₂O₃ based crystal film forming method, comprising epitaxially growing a Ga₂O₃ based crystal film over a Ga₂O₃ based substrate,

wherein a growth temperature for the Ga₂O₃ based crystal film is higher than 560 degrees Celsius, and

wherein a VI/III ratio in an atmosphere adjacent to a growing surface when the Ga₂O₃ based crystal film is grown is not smaller than ⅓, and not greater than 3.

[5] The Ga₂O₃ based crystal film forming method according to [4], wherein the growth temperature is not higher than 750 degrees Celsius, and

wherein the VI/III ratio is smaller than 2.

[6] A crystal laminated structure, comprising:

a Ga₂O₃ based substrate including a first group IV element; and

a Ga₂O₃ based crystal film including a second group IV element, the Ga₂O₃ based crystal film being formed over the Ga₂O₃ based substrate, and having a surface roughness (RMS) of smaller than 1 nm, and a thickness of not smaller than 300 nm,

wherein a coefficient of variation of a concentration distribution of the second group IV element in a depth direction in the Ga₂O₃ based crystal film is not more than 20 percent.

### Effects of the Invention

According to an embodiment of the invention, a Ga₂O₃ based crystal film forming method can be provided that allows the forming of a Ga₂O₃ based crystal film superior in crystal quality, as well as a crystal laminated structure with the Ga₂O₃ based crystal film.

### BRIEF DESCRIPTION OF THE DRAWINGS

The preferred embodiments according to the invention will be explained below referring to the drawings, wherein:

FIG. 1 is a vertical cross sectional view showing a crystal laminated structure in an exemplary embodiment;

FIG. 2 is a graph representing Ga₂O₃ crystal film growth rate dependences on O₃+O₂ gas mixture supply quantity and growth temperatures;

FIG. 3A is images showing surfaces of Ga₂O₃ crystal films observed by an atomic force microscope;

FIG. 3B is a table showing surface conditions visually identified from the observed images shown in FIG. 3A, and RMS value of surface roughness;

FIG. 4 is a graph representing depth direction profiles of tin (Sn) concentrations in Ga₂O₃ substrates and Ga₂O₃ crystal films, measured by secondary ion mass spectrometry (SIMS); and

FIG. 5 is images showing surfaces of tin (Sn) doped Ga₂O₃ crystal films observed by an atomic force microscope.

### DETAILED DESCRIPTION OF THE PREFERRED EMBODIMENTS

As a result of an intensive study of Ga₂O₃ based crystal films to be epitaxially grown over Ga₂O₃ based substrates, the present inventors have newly found out a dependence of crystal quality and principal plane flatness on a VI/III ratio, and a dependence of doped group IV element concentration distribution on that VI/III ratio, and have arrived at the present invention. An exemplary embodiment of the present invention will be described below.

### Embodiment

(Configuration of Crystal Laminated Structure)

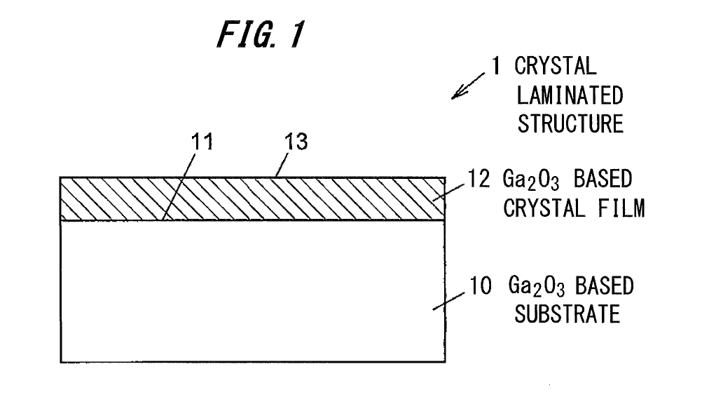

FIG. 1 is a vertical cross sectional view showing a crystal laminated structure 1 in an exemplary embodiment. The crystal laminated structure 1 includes a Ga₂O₃ based substrate 10, and a Ga₂O₃ based crystal film 12, which is formed over the Ga₂O₃ based substrate 10 by epitaxial crystal growth.

The g Ga₂O₃ based substrate 10 is a substrate made of a Ga₂O₃ based single crystal. Herein, the Ga₂O₃ based single crystal refers to a Ga₂O₃ single crystal, or, an aluminum (Al), indium (In), etc. element added Ga₂O₃ single crystal. For example, it may be an aluminum and indium added Ga₂O₃ single crystal, represented by (GaₓAl_{y}In_{(1-x-y)})₂O₃ (0<x≦1, 0≦y<1, 0<x+y≦1). Its band gap widens when aluminum is added, while its band gap narrows when indium is added. The above mentioned Ga₂O₃ single crystal has a β-type crystal structure, for example. Further, the Ga₂O₃ based substrate 10 may contain an electrically conductive impurity such as tin (Sn), etc.

A plane direction of a principal plane 11 of the Ga₂O₃ based substrate 10 is not particularly limited, but is (010), (001), (110), (210), (310), (610), (910), (101), (102), (201), (401), (−101), (−201), (−102), or (−401), for example.

The Ga₂O₃ based substrate 10 is formed by, for example, slicing a bulk crystal made of a Ga₂O₃ based single crystal grown by a melt growth method such as an FZ (Floating Zone) method, an EFG (Edge Defined Film Fed Growth) method or the like, and polishing a surface of that bulk crystal.

As with the Ga₂O₃ based substrate 10, the Ga₂O₃ based crystal film 12 is made of a Ga₂O₃ based single crystal. In addition, because the Ga₂O₃ based crystal film 12 is formed over the principal plane 11 of the Ga₂O₃ based substrate 10 by epitaxial crystal growth, a plane direction of a surface 13 of the Ga₂O₃ based crystal film 12 is the same as that of the principal plane 11 of the Ga₂O₃ based substrate 10. Further, the Ga₂O₃ based crystal film 12 may contain an electrically conductive impurity such as tin (Sn), etc.

The Ga₂O₃ based crystal film 12 is formed by a physical vapor deposition method such as an MBE (Molecular Beam Epitaxy) method.

The Ga₂O₃ based crystal film 12 is formed by epitaxial growth under growth conditions A1: growth temperatures (i.e. substrate temperatures) of not lower than 560 degrees Celsius, and VI/III ratios of smaller than ½, or greater than 2. Here, the VI/III ratios refer to ratios of atoms adhering to growing surface when the Ga₂O₃ based crystal film 12 is grown, in other words, ratios of oxygen (O) atoms and gallium (Ga) atoms that can directly contribute to the growth of the Ga₂O₃ based crystal film 12. For example, the VI/III ratio when the atoms adhering to growing surface consist of 3n oxygen atoms and 2n gallium atoms (where n is a natural number) is 1.

Growing the Ga₂O₃ based crystal film 12 epitaxially under the growth conditions A1 allows the suppression of pit formation on the surface 13 of the Ga₂O₃ based crystal film 12.

Here, the pit is a hole-shape defect caused on the surface of the crystal film. The suppression of pit formation to enhance the crystal quality of the Ga₂O₃ based crystal film 12 allows the Ga₂O₃ based crystal film 12 to be used as a superior electrically conductive layer for a semiconductor device produced using the crystal laminated structure 1.

Furthermore, the Ga₂O₃ based crystal film 12 is grown epitaxially under growth conditions A2 that are the growth conditions A1 plus conditions of growth temperatures of lower than 750 degrees Celsius, to thereby be able to produce the Ga₂O₃ based crystal film 12 having an RMS (Root Mean Square) value of the roughness of the surface 13 of smaller than 1 nm.

Here, the RMS value is obtained by measuring a curve representing a relationship between vertical height and horizontal position of the surface 13 of the Ga₂O₃ based crystal film 12 with an atomic force microscope, and finding a square root of a mean of squares of deviations of the curve from an average line thereof.

If the RMS value is great, for example, when a Schottky diode or an MESFET (Metal-Semiconductor Field Effect Transistor) is produced using the crystal laminated structure 1, the local electric field concentration is likely to occur in a Schottky electrode formed on the Ga₂O₃ based crystal film 12, leading to a lowering in device breakdown voltage. This is caused by the electric field concentration at a protruding portion of an uneven bottom surface of the Schottky electrode formed by unevenness on the surface 13 of the Ga₂O₃ based crystal film 12. As a condition for the surface roughness of the bottom surface of the Schottky electrode to suppress the electric field concentration, it is known that the RMS value is not greater than 1 nm. In other words, when the RMS value of the surface 13 of the Ga₂O₃ based crystal film 12 is not greater than 1 nm, the local electric field concentration in the Schottky electrode can be suppressed.

Further, when the Ga₂O₃ based crystal film 12 is grown doping a group IV element such as tin (Sn), etc. to act as a donor, the Ga₂O₃ based crystal film 12 is grown epitaxially under growth conditions A3 that are the growth conditions A2 plus conditions of growth temperatures of not higher than 650 degrees Celsius and VI/III ratios of not smaller than 10, to thereby be able to enhance the homogeneity of the group IV element concentration distribution in a depth direction in the Ga₂O₃ based crystal film 12.

Increasing the homogeneity of the group IV element concentration distribution in the depth direction in the Ga₂O₃ based crystal film 12 is effective especially in vertical semiconductor device production in which electric current flows in the thickness direction of the Ga₂O₃ based crystal film 12.

Further, the Ga₂O₃ based crystal film 12 may be formed by epitaxial growth under growth conditions B1 of growth temperatures of higher than 560 degrees Celsius, and VI/III ratios of not smaller than ⅓, and not greater than 3.

Growing the Ga₂O₃ based crystal film 12 epitaxially under the growth conditions B1 allows the suppression of pit formation on the surface 13 of the Ga₂O₃ based crystal film 12, as with the case of epitaxial growth under the growth conditions A1.

Furthermore, Ga₂O₃ crystal is grown epitaxially under growth conditions B2 that are the growth conditions B1 plus conditions of growth temperatures of not higher than 750 degrees Celsius and VI/III ratios of smaller than 2, to thereby be able to form the Ga₂O₃ based crystal film 12 having an RMS value (serving as a measure of the surface roughness) of smaller than 1 nm.

(Evaluation of the Ga₂O₃ Based Crystal Film)

For the Ga₂O₃ based crystal film 12, results of evaluation of the crystal quality of the surface 13, the flatness, and the homogeneity of the group IV element concentration distribution in the depth direction are shown below. In this evaluation, Ga₂O₃ substrates with a (010) principal plane direction were used as the Ga₂O₃ based substrate 10, and Ga₂O₃ crystal films to be grown as the Ga₂O₃ based crystal film 12 were formed by the MBE method, in conditions of growth temperatures of 560 to 750 degrees Celsius, a growth time of 30 minutes, and a gallium BEP (Beam Equivalent Pressure) of 2.1×10⁻⁴ Pa. In addition, an O₃+O₂ gas mixture (i.e. a mixture of ozone (O₃) and oxygen (O₂) gases) was used as an oxygen source for the Ga₂O₃ based crystal film growth. The mixing ratio of ozone (O₃) and oxygen (O₂) was about 5 percent ozone (O₃) and about 95 percent oxygen (O₂).

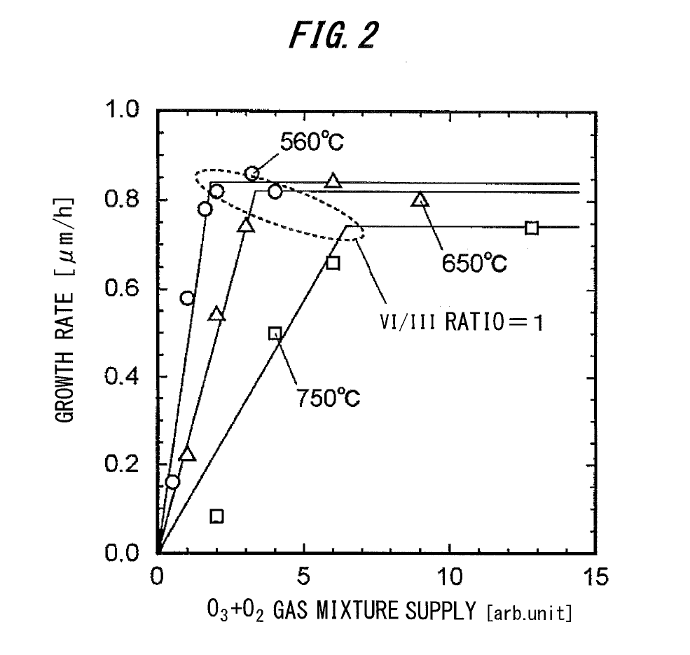

FIG. 2 is a graph representing Ga₂O₃ crystal film growth rate dependences on O₃+O₂ gas mixture supply quantity and growth temperatures. In FIG. 2, the horizontal axis is the O₃+O₂ gas mixture supply quantity [arb. unit] to the surface of the Ga₂O₃ substrate, while the vertical axis is the Ga₂O₃ crystal film growth rate [μm/h].

The gallium supply quantity was constant because the BEP was fixed at 2.1×10⁻⁴ Pa. During increasing the O₃+O₂ gas mixture supply quantity from zero, when the Ga₂O₃ crystal film growth rate was rising, the VI/III ratio was smaller than 1, i.e. VI/III ratio<1, and after the growth rate was saturated, the VI/III ratio was greater than 1, i.e. VI/III ratio>1.

In FIG. 2, the dotted line bounded area where the Ga₂O₃ crystal film growth rate rising stops is the area where VI/III ratio=about 1, and the area in which the O₃+O₂ gas mixture supply quantity is smaller than in that dotted line bounded area is the area where VI/III ratio<1, while the area in which the O₃+O₂ gas mixture supply quantity is larger than in that dotted line bounded area is the area where VI/III ratio>1.

The O₃+O₂ gas mixture was conically emitted from a pipe installed on the central axis of the substrate towards the surface of the substrate. Here, the O₃+O₂ gas mixture supply quantity to the surface of the Ga₂O₃ substrate was set at 1 arb. unit when the distance between the substrate and the pipe was set at 30 mm, and the O₃+O₂ gas mixture flow rate was set at 1 sccm. For example, when the distance between the substrate and the pipe is set at 15 mm being half of 30 mm while the O₃+O₂ gas mixture flow rate is being held at 1 sccm, the concentration of the O₃+O₂ gas mixture adjacent to the growing surface of the Ga₂O₃ crystal film is four times higher, therefore the O₃+O₂ gas mixture supply quantity is 4 arb. unit.

From FIG. 2, for each growth temperature, relationships of the substrate and O₃+O₂ gas mixture supply conditions to the VI/III ratios were obtained, and relationships of the surface crystal quality, the flatness, and the homogeneity of the group IV element concentration distribution in the depth direction of the Ga₂O₃ crystal films, to the VI/III ratios were investigated.

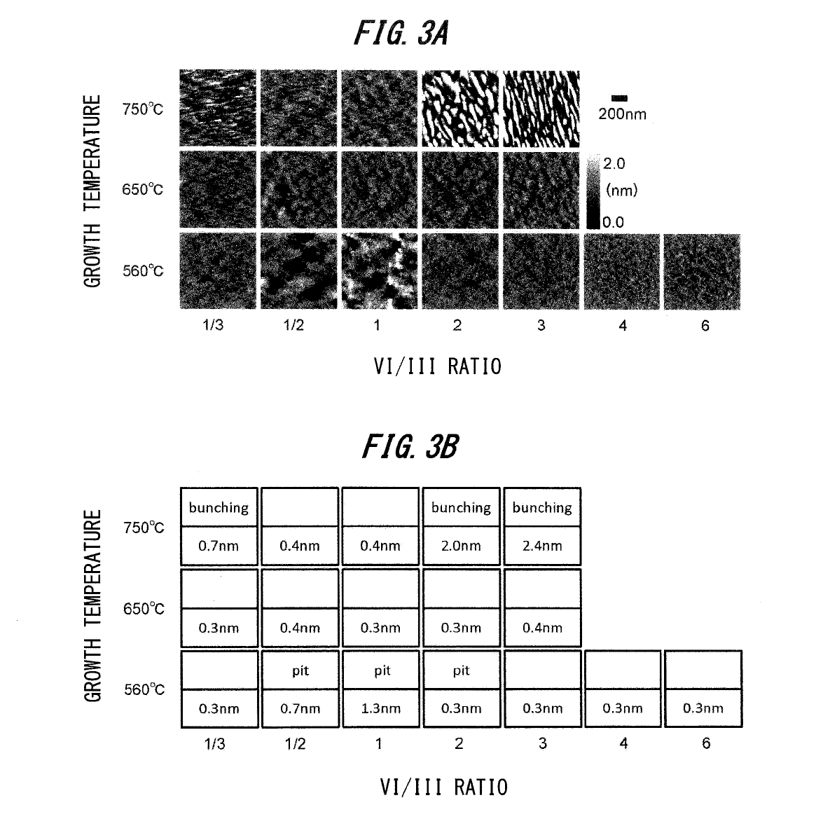

FIG. 3A is images showing the surfaces of the Ga₂O₃ crystal films observed by an atomic force microscope. FIG. 3A represents the dependences of the surface conditions of the Ga₂O₃ crystal films on the growth temperatures and the VI/III ratios. The length of one side of each image corresponds to approximately 1 μm on the surfaces of the Ga₂O₃ crystal films.

FIG. 3B is a table showing the surface conditions visually identified from the observed images shown in FIG. 3A, and the RMS values of the surface roughness. In an upper side of each frame corresponding to the observed images, respectively, of FIG. 3A is shown a surface condition, which is a “bunching” representing that a step bunching which is a wavy morphology was observed, or a “pit” representing that a pit which is a hole-shape defect was observed, or a blank representing that no step bunching and pit were observed. Also, a numerical value in a lower side of each frame represents an RMS value of surface roughness.

The pit formation indicates that the crystal quality of the Ga₂O₃ crystal film is low. Further, when the step bunching occurs, although there is no problem with the crystal quality, the flatness is poor, and the RMS value of the surface roughness increases.

As shown in FIGS. 3A and 3B, when the Ga₂O₃ crystal is grown under the growth conditions A1 of growth temperatures of not lower than 560 degrees Celsius, and VI/III ratios of smaller than ½, or greater than 2, it is possible to form the Ga₂O₃ crystal film having substantially no pits on its surface.

Also, when the g Ga₂O₃ crystal is grown under the conditions of growth temperatures of not lower than 560 degrees Celsius, and VI/III ratios of not greater than ⅓, or not smaller than 3, it is possible to more securely suppress the pit formation.

Furthermore, by epitaxially growing the Ga₂O₃ crystal under the growth conditions A2 of growth temperatures of not lower than 560 degrees Celsius, and lower than 750 degrees Celsius, and VI/III ratios of smaller than ½, or greater than 2, it is possible to form the Ga₂O₃ crystal film having substantially no pits on its surface, and having an RMS value of its surface roughness of smaller than 1 nm.

In addition, when the Ga₂O₃ crystal is grown under the conditions of growth temperatures of not lower than 560 degrees Celsius, and not higher than 650 degrees Celsius, and VI/III ratios of not greater than ⅓, or not smaller than 3, it is possible to more securely suppress the pit formation, and further enhance the flatness.

In addition, by epitaxially growing the Ga₂O₃ crystal under the growth conditions B1 of growth temperatures of higher than 560 degrees Celsius, and VI/III ratios of not smaller than ⅓, and not greater than 3, it is possible to form the Ga₂O₃ crystal film having substantially no pits on its surface.

Also, when the Ga₂O₃ crystal is grown under the conditions of growth temperatures of not lower than 650 degrees Celsius, and VI/III ratios of not smaller than ⅓, and not greater than 3, it is possible to more securely suppress the pit formation.

Furthermore, by epitaxially growing the Ga₂O₃ crystal under the growth conditions B2 of growth temperatures of higher than 560 degrees Celsius, and not higher than 750 degrees Celsius, and VI/III ratios of greater than ⅓, and smaller than 2, it is possible to form the Ga₂O₃ crystal film having substantially no pits on its surface, and having an RMS value of its surface roughness of smaller than 1 nm.

In addition, when the Ga₂O₃ crystal is grown under the conditions of growth temperatures of not lower than 650 degrees Celsius, and not higher than 750 degrees Celsius, and VI/III ratios of not smaller than ½, and not greater than 1, it is possible to more securely suppress the pit formation, and further enhance the flatness.

Next, when the Ga₂O₃ crystal film was grown doping a group IV element, the homogeneity of the group IV element concentration distribution in the depth direction was investigated. Here, the growth temperature for the Ga₂O₃ crystal film was set at 560 degrees Celsius, and the VI/III ratio was set at 1, 2, or 10. In this investigation, tin (Sn) was used as the group IV element.

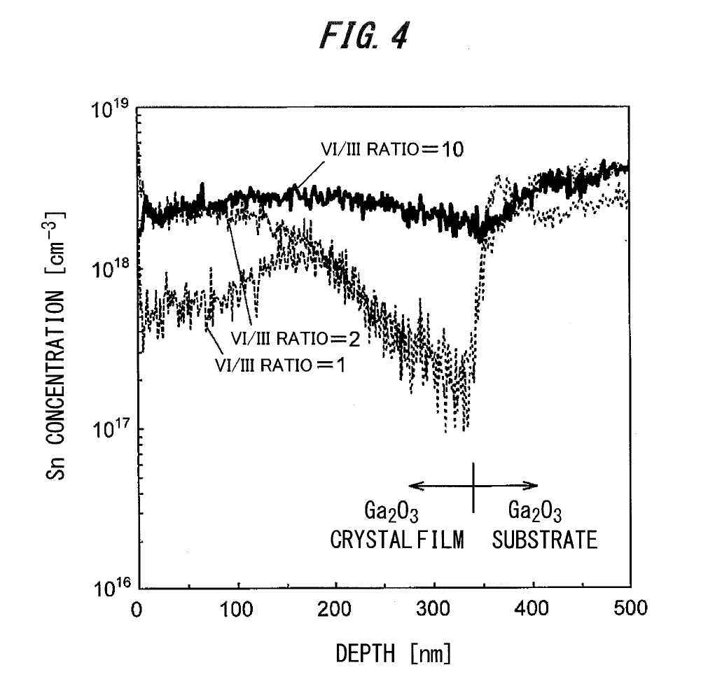

FIG. 4 is a graph representing depth direction profiles of the tin (Sn) concentrations in the Ga₂O₃ substrates and the Ga₂O₃ crystal films, measured by secondary ion mass spectrometry (SIMS). In FIG. 4, the horizontal axis represents the depth [μm] from the surface of the Ga₂O₃ crystal films, while the vertical axis represents the tin (Sn) concentration [cm⁻³].

The area from the surface to a depth of the order of 330 nm is the Ga₂O₃ crystal films, while the area deeper than 330 nm is the Ga₂O₃ substrates. FIG. 4 shows the results of measurement of the three samples having different VI/III ratios, but in any of the samples, the Ga₂O₃ substrates are higher in the average of the tin concentration than the Ga₂O₃ crystal films.

FIG. 4 shows that the tin concentration distribution in the depth direction is inhomogeneous when the VI/III ratio is 1 or 2, and that the tin concentration distribution in the depth direction is substantially homogeneous when the VI/III ratio is 10. When the VI/III ratio is 10, the tin concentration distribution in the depth direction falls within the range of the order of 2.5×10¹⁸±0.5×10¹⁸ cm⁻³, so its coefficient of variation (its maximum absolute deviation to mean ratio) is being reduced to not more than 20 percent. From this, it is found that the tin concentration distribution in the depth direction of the Ga₂O₃ crystal film can be substantially homogenized by setting the VI/III ratio at not smaller than 10.

Incidentally, when the VI/III ratio is 1 or 2, the tin concentration in the Ga₂O₃ crystal film is low in the area adjacent to the Ga₂O₃ substrate because the doping of the tin is slower than the growth of the Ga₂O₃ crystal and some tin not doped into this area is segregated adjacent to the surface of the Ga₂O₃ crystal film. This can be confirmed by the fact that when the VI/III ratio in FIG. 4 is 1 or 2, the tin concentration profiles are being rising rapidly at a depth of about 0.

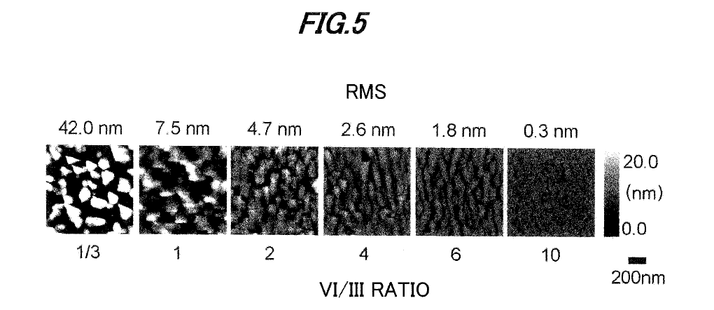

FIG. 5 is images showing surfaces of the tin doped Ga₂O₃ crystal films observed by an atomic force microscope. The Ga₂O₃ crystal films shown in FIG. 5, as with the example shown in FIG. 4, were formed at a growth temperature of 560 degrees Celsius, and were doped with the tin having a target of a concentration of 2×10¹⁸ to 3×10¹⁸ cm⁻³. The length of one side of each image corresponds to approximately 1 μm on the surfaces of the Ga₂O₃ crystal films.

As shown in FIG. 5, the Ga₂O₃ crystal films with the VI/III ratio of 6 or smaller have their rough surface, while the surface of the Ga₂O₃ crystal film with the VI/III ratio of 10 has the RMS of 0.3 nm, and is flat, as with the case of no tin doping. From this, it is found that when the VI/III ratio is 6 or smaller, the abnormal growth is caused by the surface segregation of the tin, while when the VI/III ratio is at least 10 or higher, the segregation can be suppressed. Thus, it is found that when the growth temperature is 560 degrees Celsius, setting the VI/III ratio at not smaller than 10 allows the tin doped Ga₂O₃ crystal film to have the good flatness of its surface.

Also, because as shown in FIG. 3A, if the growth temperature is 750 degrees Celsius or higher, at the VI/III ratios of 2 or higher, a step bunching occurs on the surface, it is difficult to suppress the segregation of the tin to improve the flatness. On the other hand, because if the growth temperature is 650 degrees Celsius or lower, the flatness can be good even at the higher VI/III ratios, it can be said that when the growth temperature is not higher than 650 degrees Celsius, setting the VI/III ratio at not smaller than 10 allows the tin doped Ga₂O₃ crystal film to have the good flatness of its surface.

Although in the above evaluation, as described above, the Ga₂O₃ substrates were used as the Ga₂O₃ based substrate 10 while the Ga₂O₃ crystal films were grown as the Ga₂O₃ based crystal film 12, similar evaluation results are achieved even when a Ga₂O₃ based substrate other than the Ga₂O₃ substrate is used, or even when a Ga₂O₃ based crystal film other than the Ga₂O₃ crystal film is used. Further, even when as the donor, a group IV element other than the tin, such as silicon (Si), germanium (Ge) or the like is used, similar evaluation results are achieved. Further, a group IV element (referred to as a first group IV element) to be doped into the Ga₂O₃ based substrate 10, and a group IV element (referred to as a second group IV element) to be doped into the Ga₂O₃ based crystal film 12 may be the same or be different. In addition, the plane direction of the principal plane of the Ga₂O₃ based substrate and the oxygen source for the Ga₂O₃ crystal film growth are also not limited.

### Advantageous Effects of the Embodiment

With the above described embodiment, it is possible to form the Ga₂O₃ based crystal film superior in the crystal quality and the flatness of the principal plane. Also, when doping a group IV element into the Ga₂O₃ based crystal film as the donor, it is possible to substantially homogenize the group IV element concentration distribution in the depth direction in the Ga₂O₃ crystal film.

In addition, since the Ga₂O₃ based crystal film is superior in the crystal quality and the flatness of the principal plane, it is possible to grow the high quality crystal film over the g Ga₂O₃ based crystal film. This allows the use of the crystal laminated structure containing the Ga₂O₃ based crystal film in the present embodiment in high quality semiconductor device production.

Further, the capability to substantially homogenize the group IV element concentration distribution in the depth direction in the Ga₂O₃ crystal film allows use as a superior constituent member of a vertical semiconductor device to be energized in the thickness direction of the Ga₂O₃ crystal film.

Although the exemplary embodiment of the present invention has been described above, the invention is not limited to the above described exemplary embodiment, but various modifications may be made without departing from the spirit and scope of the invention.

Further, the above described exemplary embodiment should not be construed to limit the invention in the appended claims. It should also be noted that not all the combinations of the features described in the above exemplary embodiment are essential to the means for solving the problems of the invention.

What is claimed is:

1. A Ga₂O₃ based crystal film forming method, comprising epitaxially growing a Ga₂O₃ based crystal film over a Ga₂O₃ based substrate,
wherein a growth temperature for the Ga₂O₃ based crystal film is not lower than 560 degrees Celsius, and
wherein a VI/III ratio in an atmosphere adjacent to a growing surface when the Ga₂O₃ based crystal film is grown is smaller than ½, or greater than 2.

2. The Ga₂O₃ based crystal film forming method according to claim 1, wherein the growth temperature is lower than 750 degrees Celsius.

3. The Ga₂O₃ based crystal film forming method according to claim 2, further comprising doping the Ga₂O₃ based crystal film with a group IV element while growing the crystal film,
wherein the growth temperature is not higher than 650 degrees Celsius, and
wherein the VI/III ratio is not smaller than 10.

4. A Ga₂O₃ based crystal film forming method, comprising epitaxially growing a Ga₂O₃ based crystal film over a Ga₂O₃ based substrate,
wherein a growth temperature for the Ga₂O₃ based crystal film is higher than 560 degrees Celsius, and
wherein a VI/III ratio in an atmosphere adjacent to a growing surface when the Ga₂O₃ based crystal film is grown is not smaller than ⅓, and not greater than 3.

5. The Ga₂O₃ based crystal film forming method according to claim 4, wherein the growth temperature is not higher than 750 degrees Celsius, and
wherein the VI/III ratio is smaller than 2.

6. A crystal laminated structure, comprising:
a Ga₂O₃ based substrate including a first group IV element; and
a Ga₂O₃ based crystal film including a second group IV element, the Ga₂O₃ based crystal film being formed over the Ga₂O₃ based substrate, and having a surface roughness (RMS) of smaller than 1 nm, and a thickness of not smaller than 300 nm,
wherein a coefficient of variation of a concentration distribution of the second group IV element in a depth direction in the Ga₂O₃ based crystal film is not more than 20percent.
